(19) United States
(12) Patent Application Publication
(10) Pub. No.: US 2023/0121015 A1
(43) Pub. Date: Apr. 20, 2023

(54) GATE DRIVING METHOD, GATE DRIVING CIRCUIT AND DISPLAY DEVICE

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Mindong ZHENG, Beijing (CN); Yongxian XIE, Beijing (CN); Qiang LIU, Beijing (CN); Yifeng ZOU, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN)

(21) Appl. No.: 16/957,348

(22) PCT Filed: Aug. 12, 2019
(86) PCT No.: PCT/CN2019/100157

§ 371 Date: Jun. 23, 2020

(51) Int. Cl. G09G 3/20; G11C 19/28

(52) U.S. Cl. CPC G09G 3/20; G11C 19/28; G09G 2300/0408; G09G 2310/0286; G09G 2310/0267; G09G 2320/041; G09G 2320/043; G09G 2330/02

(57) ABSTRACT

A gate driving circuit includes: a pull-up signal output end connected to an input end of a charging circuitry in a shift register unit and configured to apply a pull-up signal to the shift register unit; a pull-down signal output end connected to an input end of a resetting circuitry in the shift register unit and configured to apply a pull-down signal to the shift register unit; and a current detection circuitry connected to the pull-up signal output end and configured to detect a current value outputted by the pull-up signal output end, and/or connected to the pull-down signal output end and configured to detect a current value outputted by the pull-down signal output end. The pull-up signal output end is further configured to output the pull-up signal adjusted in accordance with the current value detected by the current detection circuitry.

### CROSS-REFERENCE TO RELATED APPLICATION

This application is the U.S. national phase of PCT Application No. PCT/CN2019/100157 filed on Aug. 12, 2019, which is incorporated herein by reference in its entirety.

### TECHNICAL FIELD

The present disclosure relates to the field of display technology, in particular to a gate driving method, a gate driving circuit and a display device.

### BACKGROUND

In the display industry, in order to reduce a manufacture cost of a display panel and provide the display panel with a narrow bezel, a Gate Driver on Array (GOA) technology has been adopted by more and more gate driving circuits, i.e., a gate switching circuit is integrated into an array substrate of the display panel.

However, for a GOA product, usually a service life of a display device is short due to characteristic offset of an internal transistor. In addition, changes in an ON-state current and an OFF-state current of the transistor at a high or low temperature may also lead to a display defect of the display device.

### SUMMARY

An object of the present disclosure is to provide a gate driving method, a gate driving circuit and a display device so as to solve the above-mentioned problems.

In one aspect, the present disclosure provides in some embodiments a gate driving circuit, including: a pull-up signal output end connected to an input end of a charging circuitry in a shift register unit and configured to apply a pull-up signal VGH to the shift register unit; a pull-down signal output end connected to an input end of a resetting circuitry in the shift register unit and configured to apply a pull-down signal VGL to the shift register unit; and a current detection circuitry connected to the pull-up signal output end and configured to detect a current value outputted by the pull-up signal output end, and/or connected to the pull-down signal output end and configured to detect a current value outputted by the pull-down signal output end. The pull-up signal output end is further configured to output the pull-up signal VGH adjusted in accordance with the current value detected by the current detection circuitry, and a voltage value of the adjusted pull-up signal corresponds to the current value detected by the current detection circuitry.

In another aspect, the present disclosure provides in some embodiments a gate driving method for the above-mentioned gate driving circuit, including: detecting, by a current detection circuitry, a current value outputted by a pull-up signal output end and/or a current value outputted by a pull-down signal output end; and controlling the pull-up signal output end to output a pull-up signal VGH adjusted in accordance with the current value detected by the current detection circuitry. A voltage value of the adjusted pull-up signal VGH corresponds to the current value detected by the current detection circuitry.

In some possible embodiments of the present disclosure, the current value detected by the current detection circuitry is the current value outputted by the pull-up signal output end. The controlling the pull-up signal output end to output the pull-up signal VGH adjusted in accordance with the current value detected by the current detection circuitry includes: when the current value outputted by the pull-up signal output end and detected by the current detection circuitry is greater than a first predetermined current value, controlling the pull-up signal output end to output the pull-up signal VGH with a voltage value smaller than a predetermined voltage value; or when the current value outputted by the pull-up signal output end and detected by the current detection circuitry is smaller than the first predetermined current value, controlling the pull-up signal output end to output the pull-up signal VGH with a voltage value greater than the predetermined voltage value.

In some possible embodiments of the present disclosure, the current value detected by the current detection circuitry is the current value outputted by the pull-down signal output end. The controlling the pull-up signal output end to output the pull-up signal VGH adjusted in accordance with the current value detected by the current detection circuitry includes: when the current value outputted by the pull-down signal output end and detected by the current detection circuitry is greater than a second predetermined current value, controlling the pull-up signal output end to output the pull-up signal VGH with a voltage value smaller than a predetermined voltage value; or when the current value outputted by the pull-down signal output end and detected by the current detection circuitry is smaller than the second predetermined current value, controlling the pull-up signal output end to output the pull-up signal VGH with a voltage value greater than a predetermined voltage value.

In some possible embodiments of the present disclosure, the controlling the pull-up signal output end to output the pull-up signal VGH adjusted in accordance with the current value detected by the current detection circuitry includes: controlling the pull-up signal output end to generate a pull-up signal VGH with a predetermined voltage value; and adjusting the voltage value of the pull-up signal VGH to a voltage value corresponding to the current value detected by the current detection circuitry in accordance with the current value detected by the current detection circuitry, and outputting the adjusted pull-up signal VGH.

In yet another aspect, the present disclosure provides in some embodiments a gate driving circuit, including: a detection sub-circuit configured to detect a current value outputted by a pull-up signal output end and/or a current value outputted by a pull-down signal output end through a current detection circuitry; and an output sub-circuit configured to control the pull-up signal output end to output a pull-up signal VGH adjusted in accordance with the current value detected by the current detection circuitry. A voltage value of the adjusted pull-up signal VGH corresponds to the current value detected by the current detection circuitry.

In some possible embodiments of the present disclosure, the current value detected by the current detection circuitry is the current value outputted by the pull-up signal output end. The output sub-circuit is further configured to: when the current value outputted by the pull-up signal output end and detected by the current detection circuitry is greater than a first predetermined current value, control the pull-up signal output end to output the pull-up signal VGH with a voltage value smaller than a predetermined voltage value; or when the current value outputted by the pull-up signal output end and detected by the current detection circuitry is smaller than the first predetermined current value, control the pull-up signal output end to output the pull-up signal VGH with a voltage value greater than the predetermined voltage value.

In some possible embodiments of the present disclosure, the current value detected by the current detection circuitry is the current value outputted by the pull-down signal output end. The output sub-circuit is further configured to: when the current value outputted by the pull-down signal output end and detected by the current detection circuitry is greater than a second predetermined current value, control the pull-up signal output end to output the pull-up signal VGH with a voltage value smaller than a predetermined voltage value; or when the current value outputted by the pull-down signal output end and detected by the current detection circuitry is smaller than the second predetermined current value, control the pull-up signal output end to output the pull-up signal VGH with a voltage value greater than a predetermined voltage value.

In some possible embodiments of the present disclosure, the output sub-circuit includes: a generation sub-circuit configured to control the pull-up signal output end to generate a pull-up signal VGH with a predetermined voltage value; and a pull-up signal voltage adjustment sub-circuit configured to adjust the voltage value of the pull-up signal VGH to a voltage value corresponding to the current value detected by the current detection circuitry in accordance with the current value detected by the current detection circuitry. And the output sub-circuit is configured to output the adjusted pull-up signal VGH.

In still yet another aspect, the present disclosure provides in some embodiments a display device including the above-mentioned gate driving circuit.

In still yet another aspect, the present disclosure provides in some embodiments a display device, including a processor, a memory, and a computer program stored in the memory and executed by the processor. The processor is configured to execute the computer program so as to implement the above-mentioned gate driving method.

In still yet another aspect, the present disclosure provides in some embodiments a computer-readable storage medium storing therein a computer program. The computer program is executed by a processor so as to implement the above-mentioned gate driving method.

### BRIEF DESCRIPTION OF THE DRAWINGS

FIG. 1 is an oscillogram showing characteristic offset of a transistor in a conventional GOA product;

FIG. 2 is an oscillogram showing an ON-state current of the conventional GOA product in a low-temperature environment;

FIG. 3 is an oscillogram showing the ON-state current of the conventional GOA product in a high-temperature environment;

FIG. 4 is a schematic view showing a gate driving circuit according to certain embodiments of the present disclosure;

FIG. 5 is a schematic view showing a connection mode of a current detection circuitry and a pull-up signal voltage adjustment sub-circuit in the gate driving circuit according to certain embodiments of the present disclosure;

FIG. 6A is an oscillogram showing a pull-up signal when a voltage value of the pull-up signal has not been adjusted yet according to certain embodiments of the present disclosure;

FIG. 6B is an oscillogram showing the pull-up signal when the voltage value of the pull-up signal has been adjusted according to certain embodiments of the present disclosure;

FIG. 6C is a comparison diagram showing waveforms of potentials at a pull-up node in a shift register unit before and after the voltage value of the pull-up signal has been adjusted according to certain embodiments of the present disclosure;

FIG. 6D is a comparison diagram showing waveforms of potentials of an output signal, an input signal and a resetting signal cascaded in the shift register unit before and after the voltage value of the pull-up signal has been adjusted according to certain embodiments of the present disclosure;

FIG. 7 is a flow chart of a gate driving method according to certain embodiments of the present disclosure;

FIG. 8 is a schematic view showing a gate driving circuit according to certain embodiments of the present disclosure; and

FIG. 9 is another schematic view showing the gate driving circuit according to certain embodiments of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

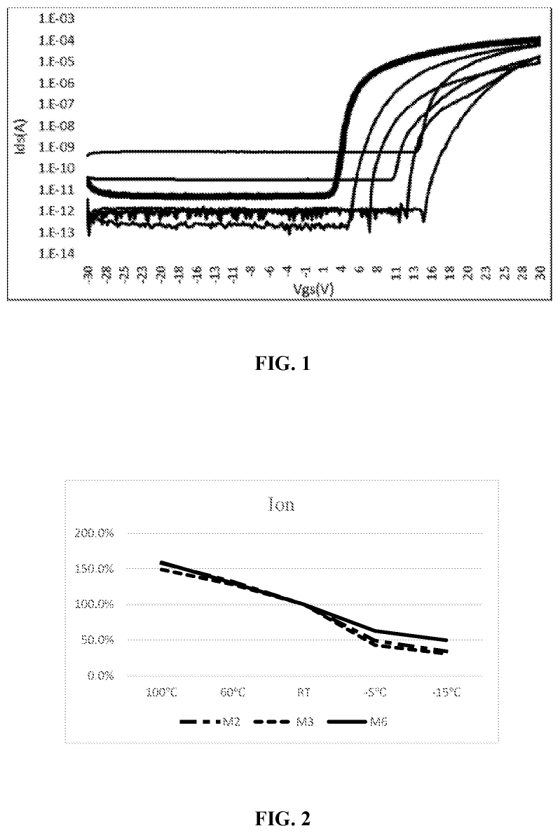

In the related art, characteristic offset of a transistor inside a GOA product is a key factor for a service life of a display device. FIG. 1 is a curve diagram showing the characteristic offset of the transistor in a 75-inch 8K display in a time order, where a horizontal axis represents a voltage difference between a gate electrode and a source electrode of the transistor, and a longitudinal axis represents a current difference between a drain electrode and the source electrode of the transistor. As shown in FIG. 1, a maximum offset value approaches to 20V, and at this time, a normal operation of a shift register unit may be seriously affected, and the service life of the display device may be shortened.

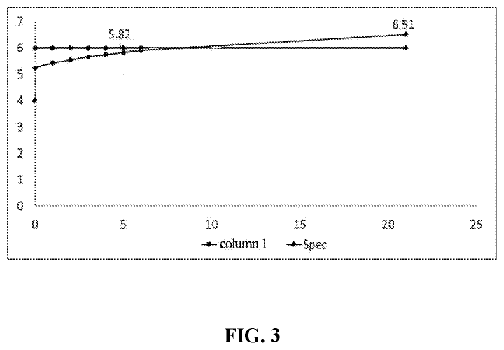

In addition, in a low-temperature environment (e.g., −40° C.), each of an ON-state current Ion and an OFF-state current Ioff of the transistor in the GOA product may decrease to be about 50% of a current value in a normal-temperature environment, as shown in FIG. 2. In FIGS. 2, M2, M3 and M6 represent three transistors in the shift register unit, a horizontal axis represents an ambient temperature for the transistors, and a longitudinal axis represents a ratio of a value of the ON-state current of the transistor to a value of an ON-state current of the transistor at a normal temperature. In this regard, a pull-up node PU of the shift register unit may be charged insufficiently, and thereby a display abnormality may occur. In a high-temperature environment (e.g., 80° C.), each of the ON-state current Ion and the OFF-state current Ioff of the transistor in the GOA product may be greater than the current value in the normal-temperature environment. In addition, the value of the ON-state current Ion of the transistor may become larger and larger with the elapse of time. After a certain period of time, the value of the ON-state current may exceed a value of the ON-state current speculated in a specification of the display device, as shown in FIG. 3, where the value of the ON-state current speculated in the specification is 6 mA. A curve in FIG. 3 shows a change in an actual value of the ON-state current of the transistor at a high temperature.

Currently, there is no scheme for solving the above-mentioned problems uniformly, so the development of the GOA product has been hindered.

An object of the present disclosure is to provide a gate driving method, a gate driving circuit and a display device, so as to improve the characteristic offset of the transistor in the GOA product as well as changes in the ON-state current and the OFF-state current of the transistor uniformly as compared with the related art.

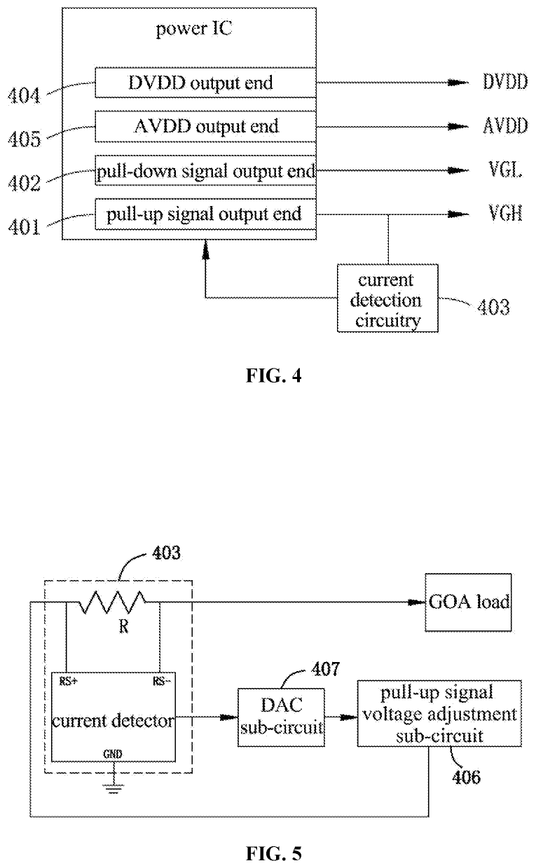

The present disclosure provides in some embodiments a gate diving circuit which, as shown in FIG. 4, includes a pull-up signal output end 401, a pull-down signal output end 402 and a current detection circuitry 403.

The pull-up signal output end 401 may be connected to an input end of a charging circuitry of the shift register unit, and configured to apply a pull-up signal VGH to the shift register unit. The pull-down signal output end 402 may be connected to an input end of a resetting circuitry in the shift register unit and configured to apply a pull-down signal VGL to the shift register unit. The current detection circuitry 403 may be connected to the pull-up signal output end 401 and configured to detect a current value outputted by the pull-up signal output end 401, and/or connected to the pull-down signal output end 402 and configured to detect a current value outputted by the pull-down signal output end 402. The pull-up signal output end 401 is further configured to output the pull-up signal VGH adjusted in accordance with the current value detected by the current detection circuitry 403, and a voltage value of the adjusted pull-up signal may correspond to the current value detected by the current detection circuitry.

According to the embodiments of the present disclosure, the current value outputted by the pull-up signal output end and/or the current value outputted by the pull-down signal output end may be detected, and then the pull-up signal VGH having the voltage value corresponding to the detected current value may be outputted, so as to improve a transistor and ensure the transistor to operate normally, thereby to prevent a service life of a display device from being shortened due to the characteristic offset of the transistor and prevent the occurrence of a display defect for the display device due to changes in an ON-state current and an OFF-state current of the transistor. As a result, through the schemes in the embodiments of the present disclosure, it is able to improve the service life and a display effect of the display device uniformly as compared with the related art.

As shown in FIG. 4, the pull-up signal output end 401 and the pull-down signal output end 402 may be two output ports of a power Integrated Circuit (IC) respectively. The pull-up signal VGH outputted by the pull-up signal output end 401 may be a high level signal capable of being used to pull up a potential at a pull-up node in the shift register unit. The pull-down signal VGL outputted by the pull-down signal output end 402 may be a low level signal capable of being used to pull down the potential at the pull-up node in the shift register unit.

As shown in FIG. 4, the power IC may further include a Digital Voltage Device Device (DVDD) output end 404 and an Analog Voltage Device Device (AVDD) output end 405. The DVDD output end is configured to supply power to a digital circuit section of the gate driving circuit, and the AVDD output end is configured to supply power to an analog circuit section of the gate driving circuit.

The current detection circuitry 403 may be connected to the pull-up signal output end 401 so as to detect the current value outputted by the pull-up signal output end 401 individually. In addition, the current detection circuitry 403 may also be connected to the pull-down signal output end 402 so as to detect the current value outputted by the pull-down signal output end 402 individually. Furthermore, the current detection circuitry 403 may be connected to both the pull-up signal output end 401 and the pull-down signal output end 402 so as to detect the current value outputted by the pull-up signal output end 401 and the current value outputted by the pull-down signal output end 402 simultaneously. A change tendency of the current value outputted by the pull-up signal output end is the same as that of the current value outputted by the pull-down signal output end, so one of them may be detected to simplify a detection procedure.

As shown in FIG. 5, when the current detection circuitry 403 is connected to the pull-up signal output end 401, the current detection circuitry 403 may include a resistor R with a known resistance and a current detector. The resistor R may be connected in series on an output path of the pull-up signal output end 401. The current detector may detect a voltage difference between two ends of the resistor R, and acquire the current value outputted by the pull-up signal output end 401 through dividing the voltage difference by the resistance.

As shown in FIG. 5, the power IC may include a pull-up signal voltage adjustment sub-circuit 406 connected to the current detection circuitry 403 and configured to adjust the voltage value of the pull-up signal VGH in accordance with the current value detected by the current detection circuitry 403, and then the pull-up signal output end 401 may output the adjusted pull-up signal VGH. The current detection circuitry 403 may communicate with the pull-up signal voltage adjustment sub-circuit 404 via a digital-to-analogue conversion (DAC) sub-circuit 407. An input end of the digital-to-analogue conversion sub-circuit 407 may be connected to an output end of the current detection circuitry 403, and an output end of the digital-to-analogue conversion sub-circuit 407 may be connected to an input end of the pull-up signal voltage adjustment sub-circuit 404.

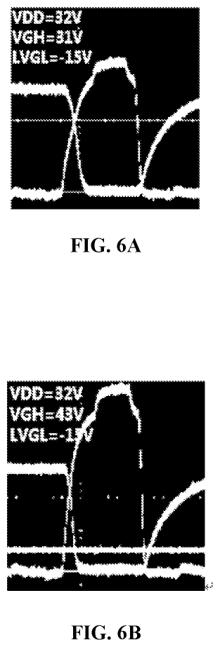

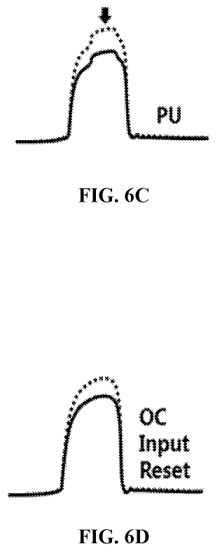

With respect to the characteristic offset of the transistor in the GOA product as well as the changes in the ON-state current and the OFF-state current of the transistor mentioned hereinabove, it is found that, when the characteristic offset occurs for the transistor as shown in FIG. 1, the current detection circuitry 403 may detect that the current value outputted by the pull-up signal output end and/or the pull-down signal output end is smaller than a current value in a normal operating state. Through increasing the voltage value of the pull-up signal VGH, as shown in FIG. 6B (FIG. 6A is an oscillogram showing the pull-up signal before the voltage value has been increased), it is able to pull up the potential at the pull-up node PU in the shift register unit, as shown in FIG. 6C (in FIG. 6C, a solid line represents the potential at the pull-up node PU before the voltage value has been increased, and a dotted line represents the potential at the pull-up node PU after the voltage value has been increased), thereby to pull up an output signal (OC), an input signal (Input) and a resetting signal (Reset) cascaded in the shift register unit to a high level as shown in FIG. 6D (in FIG. 6D, a solid line represents the potential of the cascaded signal before the voltage value has been increased, and a dotted line represents the potential of the cascaded signal after the voltage value has been increased). As a result, it is able to increase an output potential of the shift register unit and enable the shift register unit to operate normally, thereby to prolong the service life of the GOA product.

When the GOA product is in a low-temperature environment, the current detection circuitry 403 may detect that the current value outputted by the pull-up signal output end and/or the pull-down signal output end is smaller than the current value in the normal operating state. Through increasing the voltage value of the pull-up signal VGH, it is able to increase a current value of the ON-state current Ion of the transistor, thereby to improve a charging capability of the GOA product and restore the GOA product with a display abnormality caused by the insufficient charging to a normal state.

When the GOA product is in a high-temperature environment, the current detection circuitry 403 may detect that the current value outputted by the pull-up signal output end and/or the pull-down signal output end is greater than the current value in the normal operating state. Through decreasing the voltage value of the pull-up signal VGH, it is able to decrease the current value of the ON-state current Ion of the transistor to be smaller than a current value of the ON-state current speculated in the specification.

On the basis of the above three circumstances, it is found that, the current value outputted by the pull-up signal output end and/or the pull-down signal output end may be adversely affected by the above three abnormalities. With respect to the abnormality of the GOA product when the current value is smaller than the current value in the normal operating state, it is able to prevent the occurrence of the abnormality through increasing the voltage value of the pull-up signal VGH, and with respect to the abnormality of the GOA product when the current value is greater than the current value in the normal operating state, it is able to prevent the occurrence of the abnormality through decreasing the voltage value of the pull-up signal VGH.

Hence, it is able to adjust the voltage value of the pull-up signal VGH in accordance with the current value outputted by the pull-up signal output end and/or the pull-down signal output end, thereby to improve the characteristic offset of the transistor in the GOA product as well as the changes in the ON-state current and the OFF-state current of the transistor uniformly.

To be specific, when the current value outputted by the pull-up signal output end and/or the pull-down signal output end and detected by the current detection circuitry 403 is smaller than the current value in the normal operating state, the voltage value of the pull-up signal VGH may be increased to be greater than the voltage value of the pull-up signal VGH in the normal operating state. When the current value outputted by the pull-up signal output end and/or the pull-down signal output end and detected by the current detection circuitry 403 is greater than the current value in the normal operating state, the voltage value of the pull-up signal VGH may be decreased to be smaller than the voltage value of the pull-up signal VGH in the normal operating state. When the current value outputted by the pull-up signal output end and/or the pull-down signal output end and detected by the current detection circuitry 403 is equal to the current value in the normal operating state, the voltage value of the pull-up signal VGH may be the voltage value of the pull-up signal VGH in the normal operating state.

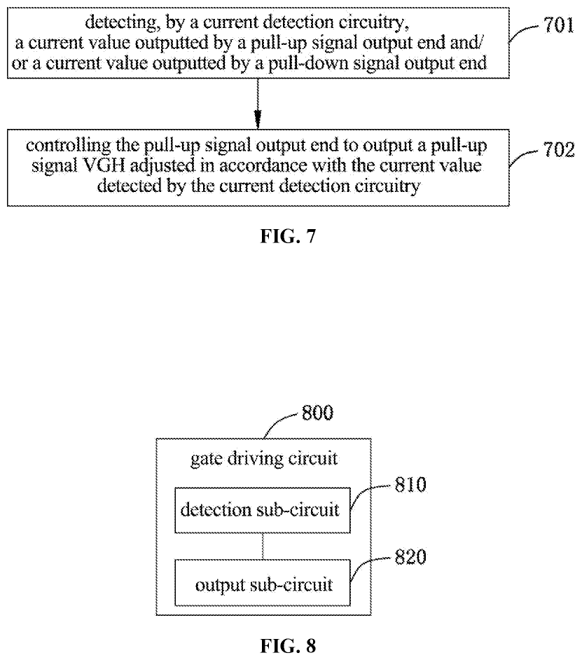

The present disclosure further provides in some embodiments a gate driving method for the above-mentioned gate driving circuit which, as shown in FIG. 7, includes: Step 701 of detecting, by the current detection circuitry, a current value outputted by the pull-up signal output end and/or a current value outputted by the pull-down signal output end; and Step 702 of controlling the pull-up signal output end to output a pull-up signal VGH adjusted in accordance with the current value detected by the current detection circuitry. A voltage value of the adjusted pull-up signal VGH may correspond to the current value detected by the current detection circuitry.

According to the embodiments of the present disclosure, the current value outputted by the pull-up signal output end and/or the current value outputted by the pull-down signal output end may be detected, and then the pull-up signal VGH having the voltage value corresponding to the detected current value may be outputted, so as to improve a transistor and ensure the transistor to operate normally, thereby to prevent a service life of a display device from being shortened due to the characteristic offset of the transistor and prevent the occurrence of a display defect for the display device due to changes in an ON-state current and an OFF-state current of the transistor. As a result, through the schemes in the embodiments of the present disclosure, it is able to improve the service life and a display effect of the display device uniformly as compared with the related art.

As shown in FIG. 4, the pull-up signal output end 401 and the pull-down signal output end 402 may be two output ports of a power IC respectively. The pull-up signal VGH outputted by the pull-up signal output end 401 may be a high level signal capable of being used to pull up a potential at a pull-up node in the shift register unit. The pull-down signal VGL outputted by the pull-down signal output end 402 may be a low level signal capable of being used to pull down the potential at the pull-up node in the shift register unit.

As shown in FIG. 4, the power IC may further include a DVDD output end 404 and an AVDD output end 405. The DVDD output end is configured to supply power to a digital circuit section of the gate driving circuit, and the AVDD output end is configured to supply power to an analog circuit section of the gate driving circuit.

The current detection circuitry 403 may be connected to the pull-up signal output end 401 so as to detect the current value outputted by the pull-up signal output end 401 individually. In addition, the current detection circuitry 403 may also be connected to the pull-down signal output end 402 so as to detect the current value outputted by the pull-down signal output end 402 individually. Furthermore, the current detection circuitry 403 may be connected to both the pull-up signal output end 401 and the pull-down signal output end 402 so as to detect the current value outputted by the pull-up signal output end 401 and the current value outputted by the pull-down signal output end 402 simultaneously. A change tendency of the current value outputted by the pull-up signal output end is the same as that of the current value outputted by the pull-down signal output end, so one of them may be detected to simplify a detection procedure.

As shown in FIG. 5, when the current detection circuitry 403 is connected to the pull-up signal output end 401, the current detection circuitry 403 may include a resistor R with a known resistance and a current detector. The resistor R may be connected in series on an output path of the pull-up signal output end 401. The current detector may detect a voltage difference between two ends of the resistor R, and acquire the current value outputted by the pull-up signal output end 401 through dividing the voltage difference by the resistance.

As shown in FIG. 5, the power IC may include a pull-up signal voltage adjustment sub-circuit 406 connected to the current detection circuitry 403 and configured to adjust the voltage value of the pull-up signal VGH in accordance with the current value detected by the current detection circuitry 403, and then the pull-up signal output end 401 may output the adjusted pull-up signal VGH. The current detection circuitry 403 may communicate with the pull-up signal voltage adjustment sub-circuit 404 via a digital-to-analogue conversion sub-circuit 407. An input end of the digital-to-analogue conversion sub-circuit 407 may be connected to an output end of the current detection circuitry 403, and an output end of the digital-to-analogue conversion sub-circuit 407 may be connected to an input end of the pull-up signal voltage adjustment sub-circuit 404.

With respect to the characteristic offset of the transistor in the GOA product as well as the changes in the ON-state current and the OFF-state current of the transistor mentioned hereinabove, it is found that, when the characteristic offset occurs for the transistor as shown in FIG. 1, the current detection circuitry 403 may detect that the current value outputted by the pull-up signal output end and/or the pull-down signal output end is smaller than a current value in a normal operating state. Through increasing the voltage value of the pull-up signal VGH, as shown in FIG. 6B (FIG. 6A is an oscillogram showing the pull-up signal before the voltage value has been increased), it is able to pull up the potential at the pull-up node PU in the shift register unit, as shown in FIG. 6C (in FIG. 6C, a solid line represents the potential at the pull-up node PU before the voltage value has been increased, and a dotted line represents the potential at the pull-up node PU after the voltage value has been increased), thereby to pull up an output signal (OC), an input signal (Input) and a resetting signal (Reset) cascaded in the shift register unit to a high level as shown in FIG. 6D (in FIG. 6D, a solid line represents the potential of the cascaded signal before the voltage value has been increased, and a dotted line represents the potential of the cascaded signal after the voltage value has been increased). As a result, it is able to increase an output potential of the shift register unit and enable the shift register unit to operate normally, thereby to prolong the service life of the GOA product.

When the GOA product is in a low-temperature environment, the current detection circuitry 403 may detect that the current value outputted by the pull-up signal output end and/or the pull-down signal output end is smaller than the current value in the normal operating state. Through increasing the voltage value of the pull-up signal VGH, it is able to increase a current value of the ON-state current Ion of the transistor, thereby to improve a charging capability of the GOA product and restore the GOA product with a display abnormality caused by the insufficient charging to a normal state.

When the GOA product is in a high-temperature environment, the current detection circuitry 403 may detect that the current value outputted by the pull-up signal output end and/or the pull-down signal output end is greater than the current value in the normal operating state. Through decreasing the voltage value of the pull-up signal VGH, it is able to decrease the current value of the ON-state current Ion of the transistor to be smaller than a current value of the ON-state current speculated in the specification.

On the basis of the above three circumstances, it is found that, the current value outputted by the pull-up signal output end and/or the pull-down signal output end may be adversely affected by the above three abnormalities. With respect to the abnormality of the GOA product when the current value is smaller than the current value in the normal operating state, it is able to prevent the occurrence of the abnormality through increasing the voltage value of the pull-up signal VGH, and with respect to the abnormality of the GOA product when the current value is greater than the current value in the normal operating state, it is able to prevent the occurrence of the abnormality through decreasing the voltage value of the pull-up signal VGH.

Hence, it is able to adjust the voltage value of the pull-up signal VGH in accordance with the current value outputted by the pull-up signal output end and/or the pull-down signal output end, thereby to improve the characteristic offset of the transistor in the GOA product as well as the changes in the ON-state current and the OFF-state current of the transistor uniformly.

To be specific, when the current value outputted by the pull-up signal output end and/or the pull-down signal output end and detected by the current detection circuitry 403 is smaller than the current value in the normal operating state, the voltage value of the pull-up signal VGH may be increased to be greater than the voltage value of the pull-up signal VGH in the normal operating state. When the current value outputted by the pull-up signal output end and/or the pull-down signal output end and detected by the current detection circuitry 403 is greater than the current value in the normal operating state, the voltage value of the pull-up signal VGH may be decreased to be smaller than the voltage value of the pull-up signal VGH in the normal operating state. When the current value outputted by the pull-up signal output end and/or the pull-down signal output end and detected by the current detection circuitry 403 is equal to the current value in the normal operating state, the voltage value of the pull-up signal VGH may be the voltage value of the pull-up signal VGH in the normal operating state.

In some possible embodiments of the present disclosure, the current value detected by the current detection circuitry may be the current value outputted by the pull-up signal output end. The controlling the pull-up signal output end to output the pull-up signal VGH adjusted in accordance with the current value detected by the current detection circuitry may include: when the current value outputted by the pull-up signal output end and detected by the current detection circuitry is greater than a first predetermined current value, controlling the pull-up signal output end to output the pull-up signal VGH with a voltage value smaller than a predetermined voltage value; or when the current value outputted by the pull-up signal output end and detected by the current detection circuitry is smaller than the first predetermined current value, controlling the pull-up signal output end to output the pull-up signal VGH with a voltage value greater than the predetermined voltage value.

In the embodiments of the present disclosure, the current detection circuitry may be connected to the pull-up signal output end, and configured to detect the current value outputted by the pull-up signal output end as a basis for the adjustment of the pull-up signal VGH in conjunction with the rules mentioned hereinabove.

The first predetermined current value may be a current value outputted by the pull-up signal output end and detected by the current detection circuitry when the transistor of the shift register unit operates normally. The predetermined voltage value may be a voltage value of the pull-up signal VGH detected by the current detection circuitry when the transistor of the shift register unit operates normally. Taking a 9HD display as an example, the predetermined voltage vale may be about 18V, and the first predetermined current value may be about 5.4 mA. In addition, the larger the size of the display device is, the larger the predetermined voltage value and the larger the first predetermined current value are.

Through comparing the current value outputted by the pull-up signal output end and currently detected by the current detection circuitry with the first predetermined current value, it is able to determine a change tendency of the current value outputted by the pull-up signal output end, thereby to determine a mode for adjusting the voltage value of the pull-up signal VGH.

When the current value outputted by the pull-up signal output end increases, i.e., when the current value outputted by the pull-up signal output end and detected by the current detection circuitry is greater than the first predetermined current value, the voltage value of the pull-up signal VGH may be decreased, i.e., the pull-up signal output end may be controlled to output the pull-up signal VGH having a voltage value smaller than the predetermined voltage value, so as to prevent the ON-state current Ion of the transistor from being greater than the ON-state current speculated in the specification when the current value outputted by the pull-up signal output end is too large.

When the current value outputted by the pull-up signal output end decreases, i.e., when the current value outputted by the pull-up signal output end and detected by the current detection circuitry is smaller than the first predetermined current value, the voltage value of the pull-up signal VGH may be increased, i.e., the pull-up signal output end may be controlled to output the pull-up signal VGH having a voltage value greater than the predetermined voltage value, so as to prevent the occurrence of the display defect of the display device due to the too small ON-state current Ion of the transistor and the insufficient GOA charging capability when the current value outputted by the pull-up signal output end is too small.

When a difference between the current value outputted by the pull-up signal output end and detected by the current detection circuitry and the first predetermined current value is larger, a voltage adjustment value of the pull-up signal VGH may be larger too.

In some possible embodiments of the present disclosure, the current value detected by the current detection circuitry may be the current value outputted by the pull-down signal output end. The controlling the pull-up signal output end to output the pull-up signal VGH adjusted in accordance with the current value detected by the current detection circuitry may include: when the current value outputted by the pull-down signal output end and detected by the current detection circuitry is greater than a second predetermined current value, controlling the pull-up signal output end to output the pull-up signal VGH with a voltage value smaller than a predetermined voltage value; or when the current value outputted by the pull-down signal output end and detected by the current detection circuitry is smaller than the second predetermined current value, controlling the pull-up signal output end to output the pull-up signal VGH with a voltage value greater than a predetermined voltage value.

In the embodiments of the present disclosure, the current detection circuitry may be connected to the pull-down signal output end, and configured to detect the current value outputted by the pull-down signal output end as a basis for the adjustment of the pull-up signal VGH in conjunction with the rules mentioned hereinabove.

The second predetermined current value may be a current value outputted by the pull-down signal output end and detected by the current detection circuitry when the transistor of the shift register unit operates normally. The predetermined voltage value may be a voltage value of the pull-up signal VGH detected by the current detection circuitry when the transistor of the shift register unit operates normally. Taking a 9HD display as an example, the predetermined voltage vale may be about 18V, and the second predetermined current value may be about 5.4 mA. In addition, the larger the size of the display device is, the larger the predetermined voltage value and the larger the second predetermined current value are.

Through comparing the current value outputted by the pull-down signal output end and currently detected by the current detection circuitry, it is able to determine a change tendency of the current value outputted by the pull-down signal output end, thereby to determine a mode for adjusting the voltage value of the pull-up signal VGH.

When the current value outputted by the pull-down signal output end increases, i.e., when the current value outputted by the pull-down signal output end and detected by the current detection circuitry is greater than the second predetermined current value, the voltage value of the pull-up signal VGH may be decreased, i.e., the pull-up signal output end may be controlled to output the pull-up signal VGH having a voltage value smaller than the predetermined voltage value, so as to prevent the ON-state current Ion of the transistor from being greater than the ON-state current speculated in the specification when the current value outputted by the pull-up signal output end is too large.

When the current value outputted by the pull-down signal output end decreases, i.e., when the current value outputted by the pull-down signal output end and detected by the current detection circuitry is smaller than the second predetermined current value, the voltage value of the pull-up signal VGH may be increased, i.e., the pull-up signal output end may be controlled to output the pull-up signal VGH having a voltage value greater than the predetermined voltage value, so as to prevent the occurrence of the display defect of the display device due to the too small ON-state current Ion of the transistor and the insufficient GOA charging capability when the current value outputted by the pull-up signal output end is too small.

When a difference between the current value outputted by the pull-down signal output end and detected by the current detection circuitry and the second predetermined current value is larger, a voltage adjustment value of the pull-up signal VGH may be larger too.

In some possible embodiments of the present disclosure, the controlling the pull-up signal output end to output the pull-up signal VGH adjusted in accordance with the current value detected by the current detection circuitry may include: controlling the pull-up signal output end to generate a pull-up signal VGH with a predetermined voltage value; adjusting the voltage value of the pull-up signal VGH to a voltage value corresponding to the current value detected by the current detection circuitry in accordance with the current value detected by the current detection circuitry; and outputting the adjusted pull-up signal VGH.

In the embodiments of the present disclosure, as shown in FIG. 5, the pull-up signal output end may generate the pull-up signal VGH with the predetermined voltage value before the output. The pull-signal voltage adjustment sub-circuit may receive a detection result from the current detection circuitry, and adjust the voltage value of the pull-up signal VGH in accordance with the detection result, so as to enable the voltage value of the pull-up signal VGH outputted by the pull-up signal output end to be an adjusted voltage value. As a result, it is able to improve the characteristic offset of the transistor in the GOA product as well as changes in the ON-state current and the OFF-state current of the transistor uniformly.

As shown in FIG. 8, the present disclosure further provides in some embodiments a gate driving circuit 800 which includes: a detection sub-circuit 810 configured to detect a current value outputted by a pull-up signal output end and/or a current value outputted by a pull-down signal output end through a current detection circuitry; and an output sub-circuit 820 configured to control the pull-up signal output end to output a pull-up signal VGH adjusted in accordance with the current value detected by the current detection circuitry. A voltage value of the adjusted pull-up signal VGH corresponds to the current value detected by the current detection circuitry.

In some possible embodiments of the present disclosure, the current value detected by the current detection circuitry may be the current value outputted by the pull-up signal output end. The output sub-circuit 820 is further configured to: when the current value outputted by the pull-up signal output end and detected by the current detection circuitry is greater than a first predetermined current value, control the pull-up signal output end to output the pull-up signal VGH with a voltage value smaller than a predetermined voltage value; or when the current value outputted by the pull-up signal output end and detected by the current detection circuitry is smaller than the first predetermined current value, control the pull-up signal output end to output the pull-up signal VGH with a voltage value greater than the predetermined voltage value.

In some possible embodiments of the present disclosure, the current value detected by the current detection circuitry may be the current value outputted by the pull-down signal output end. The output sub-circuit 820 is further configured to: when the current value outputted by the pull-down signal output end and detected by the current detection circuitry is greater than a second predetermined current value, control the pull-up signal output end to output the pull-up signal VGH with a voltage value smaller than a predetermined voltage value; or when the current value outputted by the pull-down signal output end and detected by the current detection circuitry is smaller than the second predetermined current value, control the pull-up signal output end to output the pull-up signal VGH with a voltage value greater than a predetermined voltage value.

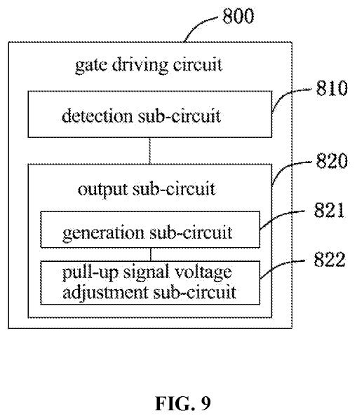

Further, as shown in FIG. 9, the output sub-circuit 820 may include: a generation sub-circuit 821 configured to control the pull-up signal output end to generate a pull-up signal VGH with a predetermined voltage value; and a pull-up signal voltage adjustment sub-circuit 822 configured to adjust the voltage value of the pull-up signal VGH to a voltage value corresponding to the current value detected by the current detection circuitry in accordance with the current value detected by the current detection circuitry. And the output sub-circuit 820 is configured to output the adjusted pull-up signal VGH.

The gate driving circuit 800 in the embodiments of the present disclosure is capable of implementing the above-mentioned gate driving method in FIG. 7, which will thus not be particularly defined herein.

According to the gate driving circuit 800 in the embodiments of the present disclosure, it is able to improve the characteristic offset of the transistor in the GOA product as well as changes in the ON-state current and the OFF-state current of the transistor uniformly.

The present disclosure further provides in some embodiments a display device including the above-mentioned gate driving circuit. The display device may be a display, a mobile phone, a flat-panel computer, a television, a wearable electronic device, or a navigator.

The present disclosure further provides in some embodiments a display device which includes, but not limited to, a Radio Frequency (RF) unit, a network module, an audio output unit, an input unit, a sensor, a display unit, a user input unit, an interface unit, a memory, a processor, and a power source. It should be appreciated that, the above structure shall not be construed as limiting the display device. The display device may include more or fewer members, or some members may be combined, or the members may be arranged in different modes.

The processor is configured to: detect a current value outputted by a pull-up signal output end and/or a current value outputted by a pull-down signal output end; and control the pull-up signal output end to output a pull-up signal VGH adjusted in accordance with the current value detected by the current detection circuitry. A voltage value of the adjusted pull-up signal VGH may correspond to the current value detected by the current detection circuitry.

In some possible embodiments of the present disclosure, the current value detected by the current detection circuitry may be the current value outputted by the pull-up signal output end. When controlling the pull-up signal output end to output the pull-up signal VGH adjusted in accordance with the current value detected by the current detection circuitry, the processor is further configured to: when the current value outputted by the pull-up signal output end and detected by the current detection circuitry is greater than a first predetermined current value, control the pull-up signal output end to output the pull-up signal VGH with a voltage value smaller than a predetermined voltage value; or when the current value outputted by the pull-up signal output end and detected by the current detection circuitry is smaller than the first predetermined current value, control the pull-up signal output end to output the pull-up signal VGH with a voltage value greater than the predetermined voltage value.

In some possible embodiments of the present disclosure, the current value detected by the current detection circuitry may be the current value outputted by the pull-down signal output end. When controlling the pull-up signal output end to output the pull-up signal VGH adjusted in accordance with the current value detected by the current detection circuitry, the processor is further configured to: when the current value outputted by the pull-down signal output end and detected by the current detection circuitry is greater than a second predetermined current value, control the pull-up signal output end to output the pull-up signal VGH with a voltage value smaller than a predetermined voltage value; or when the current value outputted by the pull-down signal output end and detected by the current detection circuitry is smaller than the second predetermined current value, control the pull-up signal output end to output the pull-up signal VGH with a voltage value greater than a predetermined voltage value.

In some possible embodiments of the present disclosure, when controlling the pull-up signal output end to output the pull-up signal VGH adjusted in accordance with the current value detected by the current detection circuitry, the processor is further configured to: control the pull-up signal output end to generate a pull-up signal VGH with a predetermined voltage value; adjust the voltage value of the pull-up signal VGH to a voltage value corresponding to the current value detected by the current detection circuitry in accordance with the current value detected by the current detection circuitry; and output the adjusted pull-up signal VGH.

The display device is capable of implementing the procedures of the gate driving circuit mentioned hereinabove, which will thus not be particularly defined herein.

According to the display device in the embodiments of the present disclosure, it is able to improve the characteristic offset of the transistor in the GOA product as well as changes in the ON-state current and the OFF-state current of the transistor uniformly.

The present disclosure further provides in some embodiments a display device, including a processor, a memory, and a computer program stored in the memory and executed by the processor. The processor is configured to execute the computer program so as to implement the above-mentioned gate driving method with a same technical effect, which will thus not be particularly defined herein.

The present disclosure further provides in some embodiments a computer-readable storage medium storing therein a computer program. The computer program is executed by a processor so as to implement the above-mentioned gate driving method with a same technical effect, which will thus not be particularly defined herein. The computer-readable storage medium may be a Read-Only Memory (ROM), a Random Access Memory (RAM), a magnetic disk or an optical disk.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A gate driving circuit, comprising:
a pull-up signal output end connected to an input end of a charging circuitry in a shift register unit and configured to apply a pull-up signal VGH to the shift register unit;
a pull-down signal output end connected to an input end of a resetting circuitry in the shift register unit and configured to apply a pull-down signal VGL to the shift register unit; and
a current detection circuitry connected to the pull-up signal output end and configured to detect a current value outputted by the pull-up signal output end, and/or connected to the pull-down signal output end and configured to detect a current value outputted by the pull-down signal output end,
wherein the pull-up signal output end is further configured to output the pull-up signal VGH adjusted in accordance with the current value detected by the current detection circuitry, and a voltage value of the adjusted pull-up signal corresponds to the current value detected by the current detection circuitry.

2. A gate driving method for the gate driving circuit according to claim 1, comprising:
detecting, by a current detection circuitry, a current value outputted by a pull-up signal output end and/or a current value outputted by a pull-down signal output end; and
controlling the pull-up signal output end to output a pull-up signal VGH adjusted in accordance with the current value detected by the current detection circuitry,
wherein a voltage value of the adjusted pull-up signal VGH corresponds to the current value detected by the current detection circuitry.

3. The gate driving method according to claim 2, wherein the current value detected by the current detection circuitry is the current value outputted by the pull-up signal output end,
wherein the controlling the pull-up signal output end to output the pull-up signal VGH adjusted in accordance with the current value detected by the current detection circuitry comprises:
when the current value outputted by the pull-up signal output end and detected by the current detection circuitry is greater than a first predetermined current value, controlling the pull-up signal output end to output the pull-up signal VGH with a voltage value smaller than a predetermined voltage value; or
when the current value outputted by the pull-up signal output end and detected by the current detection circuitry is smaller than the first predetermined current value, controlling the pull-up signal output end to output the pull-up signal VGH with a voltage value greater than the predetermined voltage value.

4. The gate driving method according to claim 2, wherein the current value detected by the current detection circuitry is the current value outputted by the pull-down signal output end,
wherein the controlling the pull-up signal output end to output the pull-up signal VGH adjusted in accordance with the current value detected by the current detection circuitry comprises:
when the current value outputted by the pull-down signal output end and detected by the current detection circuitry is greater than a second predetermined current value, controlling, the pull-up signal output end to output the pull-up signal VGH with a voltage value smaller than a predetermined voltage value; or
when the current value outputted by the pull-down signal output end and detected by the current detection circuitry is smaller than the second predetermined current value, controlling the pull-up signal output end to output the pull-up signal VGH with a voltage value greater than a predetermined voltage value.

5. The gate driving method according to claim 2, wherein the controlling the pull-up signal output end to output the pull-up signal VGH adjusted in accordance with the current value detected by the current detection circuitry comprises:
controlling the pull-up signal output end to generate a pull-up signal VGH with a predetermined voltage value;
adjusting the voltage value of the pull-up signal VGH to a voltage value corresponding to the current value detected by the current detection circuitry in accordance with the current value detected by the current detection circuitry; and
outputting the adjusted pull-up signal VGH.

6. A gate driving circuit, comprising:
a detection sub-circuit configured to detect a current value outputted by a pull-up signal output end and or a current value outputted by a pull-down signal output end through a current detection circuitry; and
an output sub-circuit configured to control the pull-up signal output end to output a pull-up signal VGH adjusted in accordance with the current value detected by the current detection circuitry,
wherein a voltage value of the adjusted pull-up signal VGH corresponds to the current value detected by the current detection circuitry.

7. The gate diving circuit according to claim 6, wherein the current value detected by the current detection circuitry is the current value outputted by the pull-up signal output end,
wherein the output sub-circuit is further configured to:
when the current value outputted by the pull-up signal output end and detected by the current detection circuitry is greater than a first predetermined current value, control the pull-up signal output end to output the pull-up signal VGH with a voltage value smaller than a predetermined voltage value; or
when the current value outputted by the pull-up signal output end and detected by the current detection circuitry is smaller than the first predetermined current value, control the pull-up signal output end to output the pull-up signal VGH with a voltage value greater than the predetermined voltage value.

8. The gate driving circuit according to claim 6, wherein the current value detected by the current detection circuitry is the current value outputted by the pull-down signal output end,
wherein the output sub-circuit is further configured to:
when the current value outputted by the pull-down signal output end and detected by the current detection circuitry is greater than a second predetermined current value, control the pull-up signal output end to output the pull-up signal VGH with a voltage value smaller than a predetermined voltage value; or
when the current value outputted by the pull-down signal output end and detected by the current detection circuitry is smaller than the second predetermined current value, control the pull-up signal output end to output the pull-up signal VGH with a voltage value greater than a predetermined voltage value.

9. The gate driving circuit according to claim 6, wherein the output sub-circuit comprises:
a generation sub-circuit configured to control the pull-up signal output end to generate a pull-up signal VGH with a predetermined voltage value; and
a pull-up signal voltage adjustment sub-circuit configured to adjust the voltage value of the pull-up signal VGH to a voltage value corresponding to the current value detected by the current detection circuitry in accordance with the current value detected by the current detection circuitry,
wherein the output sub-circuit is configured to output the adjusted pull-up signal VGH.

10. A display device, comprising the gate driving circuit according to claim 1.

11. A display device, comprising the gate driving circuit according to claim 6.

12. A non-transitory computer-readable storage medium storing therein a computer program, which is executed by a processor so as to implement the gate driving method according to claim 2.

13. The gate driving circuit according to claim 1, wherein the pull-up signal output end and the pull-down signal output end are two output ports of a power Integrated Circuit (IC) respectively.

14. The gate driving circuit according to claim 13, wherein the power IC further comprises a Digital Voltage Device Device (DVDD) output end and an Analog Voltage Device Device (AVDD) output end, the DVDD output end is configured to supply power to a digital circuit section of the gate driving circuit, and the AVDD output end is configured to supply power to an analog circuit section of the gate driving circuit.

15. The gate driving circuit according to claim 1, wherein when the current detection circuitry is connected to the pull-up signal output end, the current detection circuitry comprises a resistor with a known resistance and a current detector;
the resistor is connected in series on an output path of the pull-up signal output end; and
the current detector is configured to detect a voltage difference between two ends of the resistor, and acquire the current value outputted by the pull-up signal output end through dividing the voltage difference by the known resistance.

16. The gate driving circuit according to claim 13, wherein the power IC comprises a pull-up signal voltage adjustment sub-circuit connected to the current detection circuitry and configured to adjust the voltage value of the pull-up signal VGH in accordance with the current value detected by the current detection circuitry; and
the pull-up signal output end is configured to output the adjusted pull-up signal VGH.

17. The gate driving circuit according to claim 1, wherein the gate driving circuit is a Gate Driver on Array (GOA) circuit.

18. The gate driving circuit according to claim 6, wherein the gate driving circuit is a Gate Driver on Array (GOA) circuit.

19. The gate driving method according to claim 3, wherein when the gate driving method is applied to a 9HD display device, the first predetermined current value is about 5.4 mA.

20. The gate driving method according to claim 19, wherein the larger the size of the display device is, the larger the first predetermined current value is.
